(19) United States
(12) Patent Application Publication
(10) Pub. No.: US 2010/0255252 A1
(43) Pub. Date: Oct. 7, 2010

(54) NANOSTRUCTURE COMPOSITE AND METHOD OF PRODUCING THE SAME

(76) Inventors: Sang-Hyeob Kim, Daejeon-city (KR); Seung-Sik Park, Gyeongsangbuk-do (KR); Sang-Woo Kim, Gyeongsangbuk-do (KR); Gong-Gu Lee, Gyeongsangbuk-do (KR); Sung-Jin Kim, Gyeongsangbuk-do (KR); Sunglyul Maeng, Daejeon-city (KR); Sunyoung Lee, Daejeon-city (KR); Hey-Jin Myoung, Daejeon-city (KR)

Correspondence Address: LADAS & PARRY LLP, 224 SOUTH MICHIGAN AVENUE, SUITE 1600, CHICAGO, IL, 60604, US

(21) Appl. No.: 12/676,185

(22) PCT Filed: Sep. 3, 2008
(86) PCT No.: PCT/KR2008/005165

§ 371 Date: Jun. 4, 2010

(30) Foreign Application Priority Data
Sep. 3, 2007 (KR) 10-2007-0089169

(51) Int. Cl. B82B 3/00; C23C 16/40

(52) U.S. Cl. 428/141; 427/376.2; 427/248.1; 977/700; 977/840

(57) ABSTRACT

Provided is a nano structure composite and a method of manufacturing the same. More specifically, a nano structure composite that includes a substrate, a first layer formed of carbon nano structures on the substrate, and a second layer formed of metal oxide nano structures on the first layer, and a method of manufacturing the same are provided. When the nano structure composite according to the present invention is used, a device having a field emission characteristic higher efficiency than a conventional device can be realized, and also, the device can be manufactured at a lower temperature and at a lower pressure. Thus, manufacturing cost can be reduced and a large scale process can be performed.

### TECHNICAL FIELD

The present invention relates to a nanostructure composite and a method of manufacturing the same, and more particularly, to a nanostructure composite that can realize a high efficiency field emission characteristic and can be manufactured at a lower temperature and at a lower pressure, and a method of manufacturing the same. This work was supported by the IT R&D program of MIC/IITA, [2005-S-605-02, IT-BT-NT Convergent Core Technology for advanced Optoelectronic Devices and Smart Bio/Chemical Sensors]

### BACKGROUND ART

A nano composite that uses an oxide of a transition metal or a metalloid element is expected to be widely used in nano electronic device, solar cells, and display fields such as field effect transistors (FETs), single electron transistors (SETs), optical diodes, biochemical sensors, or logic circuits, and thus, active studies with regard to the nano composite have been conducted.

In particular, oxide based nano structures having semiconductor characteristics, for example, ZnO having a band gap of 3.37 eV or SnO₂ having a band gap of 3.6 eV, can be applied to photoelectronics or gas sensors. In particular, SnO₂ has a short wavelength and a low voltage operation characteristic, and thus, can be applied to a transparent electrode material.

Meanwhile, since carbon nanotubes can be deposited on a large scale substrate, there is a high possibility of using the carbon nanotubes as a field emission tip of a field emission device. Thus, studies with regard to vertical growing of the carbon nanotubes and studies to improve electrical characteristics of the carbon nanotubes have been actively conducted. However, it is very difficult to arrange the carbon nanotubes in a vertical direction to the substrate.

### DISCLOSURE OF INVENTION

### Technical Problem

To address the above and/or other problems, the present invention provides a nano structure composite that can realize a high efficiency field emission characteristic and can be manufactured at a lower temperature and at a lower pressure.

The present invention also provides a method of manufacturing a nano structure composite that can realize a high efficiency field emission characteristic and can be manufactured at a lower temperature and at a lower pressure.

### Technical Solution

According to an aspect of the present invention, there is provided a nano structure composite comprising: a substrate; a first layer formed of carbon nano structures on the substrate; and a second layer formed of metal oxide nano structures on the first layer.

The metal oxide nano structures may be nanowires. A catalyst metal may be optionally formed on ends of the metal oxide nano structures. The metal oxide may be an oxide of a metal at least one selected from the group consisting of Ti, V, Cr, Zn, Y, Zr, and Nb. The substrate may be formed of silicon, GaN, or sapphire.

According to an aspect of the present invention, there is provided a method of manufacturing a nano structure composite, comprising: forming a first layer using carbon nano structures on a substrate; annealing the first layer; dispersing a catalyst metal on the first layer; and forming a second layer of metal oxide nano structures on the first layer.

The substrate may be formed of silicon, GaN, or sapphire. The metal oxide may be an oxide of a metal at least one selected from the group consisting of Ti, V, Cr, Zn, Y, Zr, and Nb. The forming of the second layer may comprise depositing the metal oxide on the first layer using a chemical vapor deposition (CVD) method. The substrate and the first layer may be maintained at a temperature of about 300° C. to about 550° C. while the CVD is performed.

### DESCRIPTION OF DRAWINGS

The above and other features and advantages of the present invention will become more apparent by describing in detail exemplary embodiments thereof with reference to the attached drawings in which:

FIG. 1 is a conceptual drawing of a lateral view of a nano structure composite according to an embodiment of the present invention;

FIG. 2 is a field emission scanning electron microscope (FE-SEM) image of a surface of a first layer formed of carbon nano structures according to an embodiment of the present invention;

FIG. 3A is a FE-SEM image of a catalyst metal formed on the first layer formed of carbon nano structures according to an embodiment of the present invention;

FIG. 3B is a graph showing an Energy-Dispersive X-ray Spectroscopy (EDX) analysis result that proves the formation of Au particles as a catalyst metal on a surface of the first layer;

FIGS. 4 and 5 are FE-SEM images of a metal oxide based nano structure respectively grown at temperatures of 400 and 500° C. after dispersing Au nano particles as a catalyst metal on thin carbon nanotube films;

FIGS. 6A and 6B are graphs showing optical characteristic results of oxide based nano structures respectively grown at temperatures of 400 and 500° C. through ambient temperature photoluminescence (PL) analysis; and

FIG. 7 is a graph showing field emission effect of a device that uses a metal oxide nano structure grown on a carbon nanotube thin film.

### BEST MODE

The present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art. In the drawings, like reference numerals in the drawings denote like elements, and also, various elements and regions are schematically depicted. Thus, the present invention is not limited by relative sizes or gaps shown in the drawings.

The present invention provides a nano structure composite that includes a substrate, a first layer formed of carbon nano structures on the substrate, and a second layer formed of metal oxide nano structure on the first layer.

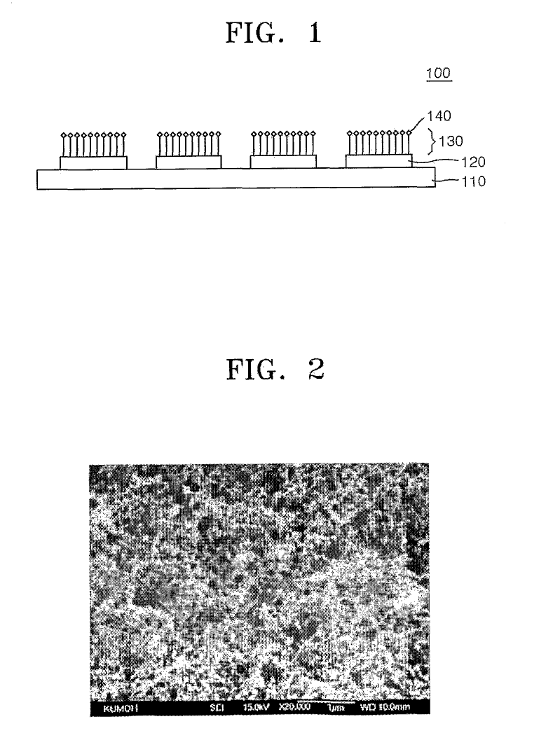

FIG. 1 is a conceptual drawing of a lateral view of a nano structure composite 100 according to an embodiment of the present invention. Referring to FIG. 1, the nano structure composite 100 includes a substrate 110, a first layer 120, and a second layer 130. The substrate 110 can be formed of silicon, gallium nitride GaN, or sapphire. If the substrate 110 is formed of GaN or sapphire, a metal oxide nano structure to be stacked on the substrate 110 grows nearly perpendicular to the substrate 110, and if the substrate 110 is formed of silicon, the metal oxide nano structure grows in an arbitrary direction with an angle of approximately 45° direction.

A carbon nano structure that constitutes the first layer 120 can be formed of a carbon nanosphere, a carbon nanotube, a carbon nanowire, a carbon nanohorn, a carbon nanofiber, a carbon nanoring, a carbon nanorod, a carbon nanobelt, a carbon powder, graphite, fullerene C₆₀, carbon black, or acetylene black, however, not limited thereto, and may be formed of carbon nanotube or carbon nanowire.

The first layer 120 can be formed to a thickness of, for example, about 1 nm to about 5000 nm, preferably, about 100 nm to about 3000 nm, and further preferably, about 1000 nm to about 2500 nm.

The metal oxide nano structure that constitutes the second layer 130 mainly a nanowire, and also, can be another one dimensional structure such as a nano belt or a nano rod. The metal oxide can be an oxide of a transition metal or a metalloid, for example, can be at least one selected from the group consisting of Ti, V, Cr, Zn, Y, Zr, and Nb.

Alternatively, a catalyst metal 140 may be formed on an end of the metal oxide nano structure that constitutes the second layer 130. The catalyst metal 140 can be formed of any material that has a self-assembling characteristic according to temperature increase, and can be formed of, for example, Au, Ag, Pt, Pd, or Cu, however, not limited thereto.

The present invention provides a method of manufacturing a nano structure composite, comprising: forming the first layer 120 which is a carbon nano structure on the substrate 110; annealing the first layer 120; distributing a catalyst metal on the first layer 120; and forming the second layer 130 which is a metal oxide nano structure on the first layer 120.

The method of forming the first layer 120 which is a carbon nano structure on the substrate 110 is not particularly limited, and can be a screen printing method, a taping method, or an inkjet printing method. If the first layer 120 is formed using the screen printing method, a paste is made by uniformly mixing single-walled or multi-walled carbon nanotubes with an organic binder, an organic solvent, a filler, and a dispersing agent, and then, the first layer 120 can be formed by pressing the paste using a pressing means such as a 3-roller mill.

The binder can be, for example, ethyl cellulose, however, not limited thereto. The organic solvent can be, for example, terpineol, butylcarbinol, or an acetate based solvent, however, not limited thereto. The filler can be, for example, glass frit which is a non-conductive material and indium tin oxide (ITO), however, not limited thereto.

After forming the first layer 120 by pressing the paste, the paste is sintered to remove the organic solvent included in the paste. Optionally, the sintering can be performed in two steps. That is, a primary sintering to remove the organic solvent and a secondary sintering to remove the organic binder. The primary sintering can be performed in a temperature range, for example, from about 100° C. to about 150° C., and the secondary sintering can be performed in a temperature range, for example, from about 300° C. to about 400° C.

FIG. 2 is a field emission scanning electron microscope (FE-SEM) image of a surface of the first layer 120 formed of carbon nano structures according to an embodiment of the present invention.

Then, a catalyst metal is distributed on the first layer 120. The catalyst metal is a catalyst for growing a metal oxide to be grown in a subsequent process. The method of distributing the catalyst metal is not particularly limited, and, for example, can be performed as the following method.

After dispersing a solution in which a salt of a catalyst metal is dissolved on the first layer 120, the catalyst metal can be dispersed on the first layer 120 by removing the solvent. The solvent can be an alcohol based solvent such as ethanol, methanol, isopropyl alcohol, and butyl alcohol, or an organic solvent such as dimethyl acetamide (DMAc), dimethylformamide, dimethylsulfoxide (DMSO), N-methylpyrrolidone, and tetrahydrofuran, however, not limited thereto.

The catalyst metal can be Au, Ag, Pt, Pd, or Cu, and a salt of these metals, such as a chloride, a nitrate, or an ammonium salt can be dissolved and dispersed. The concentration of the catalyst metal in the solution can be, for example, about 0.05 M to about 10 M.

An amount of the catalyst metal dispersed on the first layer 120 may be about 1×10⁻⁵ to about 1×10⁻³ mol/cm², and the dispersion and drying process may be repeated three to ten times.

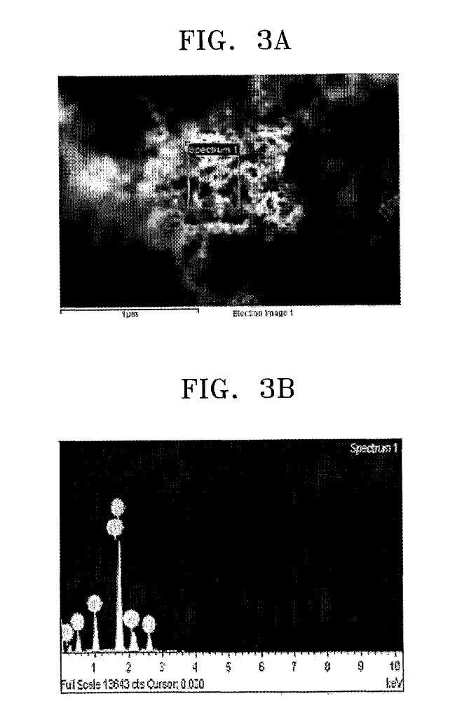

FIG. 3A is a FE-SEM image of the catalyst metal formed on the first layer 120 according to an embodiment of the present invention. FIG. 3B is a graph showing an Energy-Dispersive X-ray Spectroscopy (EDX) analysis result that proves the formation of Au particles as a catalyst metal on a surface of the first layer 120.

Then, the second layer 130 formed of metal oxide nano structures can be formed on the first layer 120. A chemical vapor deposition (CVD) method can be used to form the metal oxide nano structure. The CVD method can be of well known in the art, and can be performed as the following method.

A powder mixture in which a metal oxide powder and carbon are mixed is placed on a first zone in a reactor for CVD, and the substrate where a metal oxide nano structure is to be formed and on which the first layer is formed is placed in a second zone in the reactor. At this point, the first zone and the second zone can have a relationship that a reaction gas generated from the first zone flows into the second zone.

The metal oxide may be an oxide of a metal at least one selected from the group consisting of Ti, V, Cr, Zn, Y, Zr, and Nb.

The mixing ratio of the metal oxide powder to carbon in the first zone can be 1:1 by weight, and the first zone is maintained at a temperature of about 900 to about 1000° C. to facilitate the vaporization of the powder. Also, the second zone can be maintained at a temperature of about 300° C. to about 550° C. to grow a metal oxide nano structure. At this point, the reactor can be maintained at an inert atmosphere, for example, an inert gas, for example, He, Ne, Ar, or N₂ can be purged.

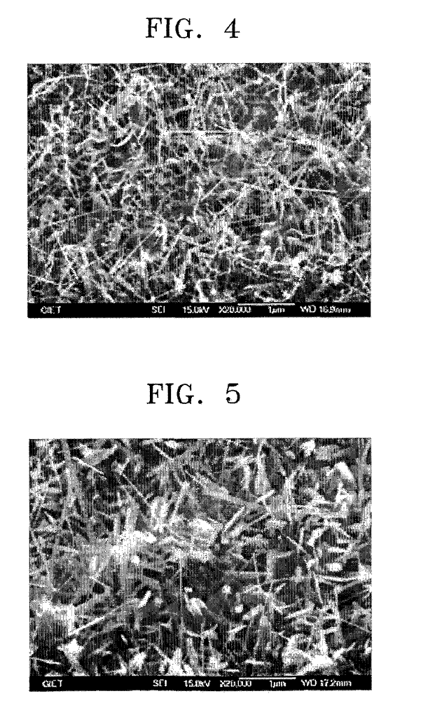

FIG. 4 is a FE-SEM image of a metal oxide based nano structure grown at a temperature of 400° C. after dispersing Au nano particles as a catalyst metal on a thin carbon nanotube film. It is seen that nanowires of ZnO having a width of about 20 to about 40 nm which is a size similar to the Au nano particles (approximately 10 nm) are grown, and the nanowires have a length of a few to a few hundreds of nm. The size of the nanowire can be readily controlled by controlling the growing time.

FIG. 5 is a FE-SEM image of a metal oxide based nano structure grown at a temperature of 500° C. after dispersing Au nano particles as a catalyst metal on a thin carbon nanotube film. It is seen that Au nano particles are located at ends of the nanowire of ZnO, which proves that the metal oxide nano wires are grown through a vapor-liquid-solid (VLS) process. Also, it is seen that various one-dimensional nano structures such as nano belts and nano rods are mixed.

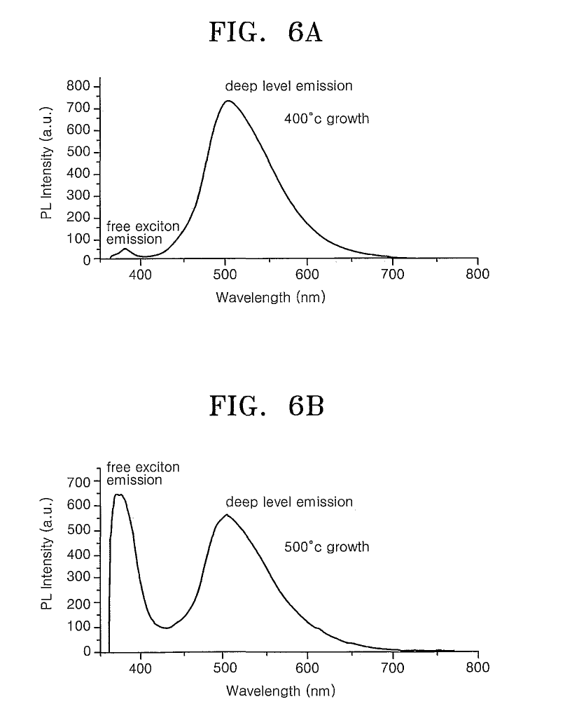

FIGS. 6A and 6B are graphs showing optical characteristic results of zinc oxide based nano structures respectively grown at temperatures of 400 and 500° C. through ambient temperature photoluminescence (PL) analysis. As shown in FIGS. 6A and 6B, free exciton light emission and deep level light emission are clearly observed.

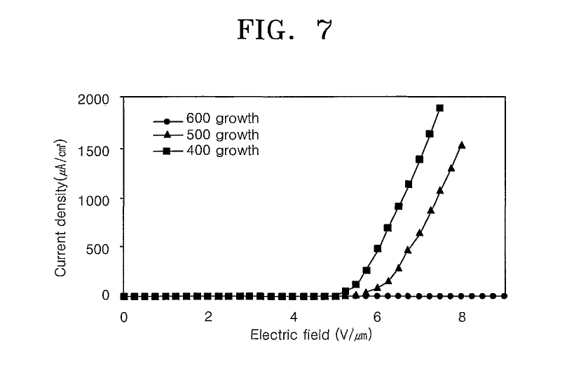

FIG. 7 is a graph showing field emission effect of a device that uses a zinc oxide nano structure grown at temperatures of 400° C., 500° C., and 600° C., respectively, on a carbon nanotube thin film. It is seen that the devices that include metal oxide nano structures grown at temperatures of 400° C. and 500° C. show relatively high field emission characteristics; however, the device that includes a metal oxide nano structure grown at a temperature of 600° C. shows a poor field emission characteristic.

The present invention also provides an electronic apparatus having a nano structure composite that includes: a substrate; a first layer formed of carbon nano structures on the substrate; and a second layer formed of metal oxide nano structures on the first layer.

The electronic apparatus can be, for example, a display device, a mobile phone, a sounder, or a computer and perimeter devices, however, not limited thereto. In particular, the display device can be a computer monitor, a television set, a portable multimedia player (PMP), a road guide device, display screens of various electronic devices, or display screens of mobile phones.

When the nano structure composite according to the present invention is used, a device having a field emission characteristic higher efficiency than a conventional device can be realized, and also, the device can be manufactured at a lower temperature and at a lower pressure. Thus, manufacturing cost can be reduced and a large scale process can be performed.

While the present invention has been particularly shown and described with reference to exemplary embodiments thereof, it will be understood by those of ordinary skill in the art that various changes in form and details may be made therein without departing from the spirit and scope of the present invention as defined by the following claims.

1. A nano structure composite comprising:
a substrate;
a first layer formed of carbon nano structures on the substrate; and
a second layer formed of metal oxide nano structures on the first layer.

2. The nano structure composite of claim 1, wherein the metal oxide nano structures are nanowires.

3. The nano structure composite of claim 2, wherein a catalyst metal is formed on ends of the metal oxide nano structures.

4. The nano structure composite of claim 1, wherein the metal oxide is an oxide of a metal at least one selected from the group consisting of Ti, V, Cr, Zn, Y, Zr, and Nb.

5. The nano structure composite of claim 1, wherein the substrate is formed of silicon, GaN, or sapphire.

6. A method of manufacturing a nano structure composite, comprising:
forming a first layer using carbon nano structures on a substrate;
annealing the first layer;
dispersing a catalyst metal on the first layer; and
forming a second layer of metal oxide nano structures on the first layer.

7. The method of claim 6, wherein the substrate is formed of silicon, GaN, or sapphire.

8. The method of claim 6, wherein the metal oxide is an oxide of a metal at least one selected from the group consisting of Ti, V, Cr, Zn, Y, Zr, and Nb.

9. The method of claim 6, wherein the forming the second layer comprises depositing the metal oxide on the first layer using a chemical vapor deposition (CVD) method.

10. The method of claim 9, wherein the substrate and the first layer are maintained at a temperature of about 300° C. to about 550° C. while the CVD is performed.
